(19) United States
(12) Patent Application Publication
(10) Pub. No.: US 2026/0323938 A1
(43) Pub. Date: Oct. 15, 2026

(54) THREE-DIMENSIONAL SEMICONDUCTOR MEMORY DEVICE

(71) Applicant: SK hynix Inc., Gyeonggi-do (KR)

(72) Inventors: Dengtao Zhao, San Jose, CA (US); Agus Tjandra, San Jose, CA (US)

(21) Appl. No.: 19/174,876

(22) Filed: Apr. 9, 2025

(51) Int. Cl. H10B 43/27; G11C 5/06; G11C 16/04; H10B 43/35

(52) U.S. Cl. CPC H10B 43/27; G11C 5/063; G11C 16/0483; H10B 43/35

(57) ABSTRACT

There is provided a three-dimensional semiconductor memory device. The three-dimensional semiconductor memory device includes a cell string including at least one select transistor, a plurality of memory cells, and at least one drain select transistor connected in series between a common source line and a bit line. The at least one source select transistor has a first channel including a first polysilicon layer, and each of the plurality of memory cells has a second channel containing a material other than polysilicon. The at least one drain select transistor has a third channel including a polysilicon layer.

### BACKGROUND

### 1. Technical Field

Embodiments of the present disclosure relate to a semiconductor memory device, and more particularly to a three-dimensional semiconductor memory device.

### 2. Related Art

Semiconductor memory devices may include a plurality of memory cells capable of storing data. In order to improve a degree of integration of semiconductor memory devices, three-dimensional (3D) memory devices in which memory cells are arranged in three-dimensions on a substrate have been proposed.

In this context, embodiments of the present disclosure arise.

### SUMMARY

Embodiments of the present disclosure are directed to a three-dimensional semiconductor memory device capable of securing a strong gate-induced drain leakage (GIDL) during an erase operation while improving conductivity of a channel.

In accordance with an embodiment of the present disclosure, there is provided a three-dimensional semiconductor memory device. The three-dimensional semiconductor memory device includes a cell string including at least one select transistor, a plurality of memory cells, and at least one drain select transistor connected in series between a common source line and a bit line. The at least one source select transistor has a first channel including a first polysilicon layer, and each of the plurality of memory cells has a second channel containing a material other than polysilicon.

The at least one drain select transistor has a third channel including a second polysilicon layer.

In accordance with an embodiment of the present disclosure, there is provided a three-dimensional semiconductor memory device. The three-dimensional semiconductor memory device may include a cell string including at least one select transistor, a plurality of memory cells, and at least one drain select transistor connected in series between a common source line and a bit line. The at least one drain select transistor has a first channel including a polysilicon layer, and each of the plurality of memory cells has a second channel containing a material other than polysilicon.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a circuit diagram illustrating a memory cell string included in a semiconductor memory device.

FIG. 2 is a perspective view illustrating a structure of a semiconductor memory device.

FIG. 3 is a diagram for describing a configuration of a semiconductor memory device.

FIG. 4 is a diagram for describing GLDL mechanism.

FIG. 5 is diagram for describing a configuration of a semiconductor memory device in accordance with one embodiment of the present disclosure.

FIG. 6 is diagram for describing a configuration of a semiconductor memory device in accordance with another embodiment of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The embodiments of the present disclosure are described herein with reference to cross-section and/or plan illustrations of the embodiments. However, the embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present disclosure.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly or indirectly on the second element or the substrate.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

It should be understood that the drawings are simplified schematic illustrations of the described devices and may not include well known details to avoid obscuring the features of the embodiments.

It should also be noted that features present in one embodiment may be used with one or more features of another embodiment without departing from the scope of the present disclosure.

It is further noted, that in the various drawings, like reference numbers designate like elements.

As used herein, singular forms are intended to include the plural forms as well, unless the context clearly indicates otherwise.

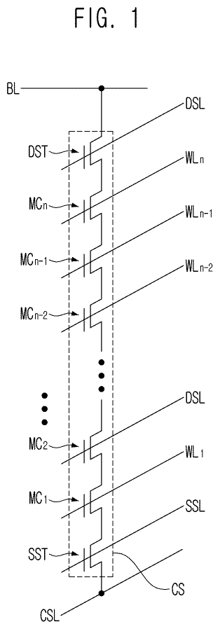

FIG. 1 is a circuit diagram illustrating a memory cell string included in a semiconductor memory device. In FIG. 1, a configuration of a memory cell string CS of a three-dimensional NAND device is illustrated.

Referring to FIG. 1, the memory cell string CS may be coupled to a bit line BL and a common source line CSL. Although a single memory cell string CS is illustrated, a plurality of memory cell strings may be coupled in parallel between the bit line BL and the common source line CSL.

The memory cell string CS may include a source select transistor SST, a plurality of memory cells MC1 to MCn, and a drain select transistor DST connected in series between the common source line CSL and the bit line BL.

The source select transistor SST may control the electrical connection between the common source line CSL and the memory cells MC1 to MCn. The source select transistor SST may be coupled to a source select line SSL, and controlled by a source gate signal (voltage) applied to the source select line SSL. Although one source select transistor SST is illustrated in FIG. 1, two or more source select transistors may be disposed in series between the common source line CSL and the memory cells MC1 to MCn.

The memory cells MC1 to MCn may be coupled in series between the source select transistor SST and the drain select transistor DST. The memory cells MC1 to MCn may be coupled to a plurality of word lines WL1 to WLn, and controlled by cell gate signals (voltages) applied to the word lines WL1 to WLn. Each of the memory cells MC1 to MCn may store single-bit data or multi-bit data.

The drain select transistor DST may control the electrical connection between the memory cells MC1 to MCn and the bit line BL. The drain select transistor DST may be coupled to a drain select line DSL, and controlled by a drain gate signal (voltage) applied to the drain select line DSL. Although one drain select transistor DST is illustrated in FIG. 1, two or more drain select transistors may be disposed in series between the bit line BL and the memory cells MC1 to MCn.

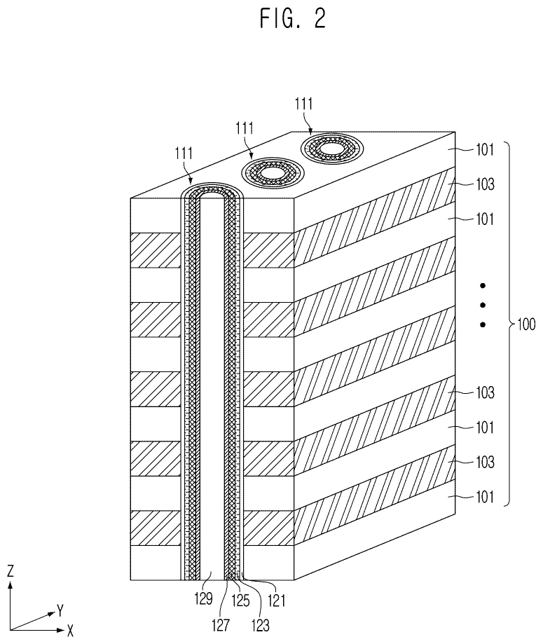

FIG. 2 is a perspective view illustrating a structure of a semiconductor memory device. In FIG. 2, a partially exploded structure of a three-dimensional NAND device is illustrated.

Referring to FIG. 2, the semiconductor memory device may include a stacked body 100, a blocking insulating layer 121, a data storage layer 123, a tunnel insulating layer 125, and a channel layer 127. The semiconductor memory device may further include a gap-filling layer 129.

The stacked body 100 may include interlayer insulating layers 101 and gate electrodes 103. Each of the interlayer insulating layers 101 and the gate electrodes 103 may be parallel to an X-Y plane. The interlayer insulating layers 101 and the gate electrodes 103 may be stacked in a Z-axis direction perpendicular to the X-Y plane. The interlayer insulating layers 101 and the lines 103 may be alternately stacked.

The interlayer insulating layers 101 may be formed of silicon oxide (e.g., SiO₂).

The gate electrodes 103 may be insulated from each other by the interlayer insulating layers 101. The gate electrodes 103 may be used as the word lines WL1 to WLn, the source select line SSL, and the drain select line SSL described with reference to FIG. 1. The gate electrodes 103 may be formed of doped semiconductor, metal, metal nitride, and metal silicide. For example, the gate electrodes 103 may be formed of a multiple layer of titanium nitride (TiN)/Tungsten(W).

The stacked body 100 may be penetrated by a channel hole 111 extending in the Z-axis direction during the fabrication process. The interlayer insulating layers 101 and the gate electrodes 103 may be defined along a sidewall of the channel hole 111. The channel hole 111 may have various shapes, such as a circle, an oval, a square, a rectangle, and a polygon.

The channel layer 127 may be formed of semiconductor, such as polysilicon or the like. The channel layer 127 may extend in the Z-axis direction along the sidewall of the channel hole 111. The channel layer 127 may form a channel area of the memory cell string CS illustrated in FIG. 1.

The blocking insulating layer 121, the data storage layer 123, and the tunnel insulating layer 125 may be interposed between the stacked body 100 and the channel layer 127. The blocking insulating layer 121, the data storage layer 123, and the tunnel insulating layer 125 may be referred to as a memory layer or an ONO layer.

The blocking insulating layer 121 may include a single layer or multiple layers. The blocking insulating layer 121 may include a silicon oxide layer or a silicon oxide/metal oxide layer. The metal oxide layer (e.g., aluminum oxide, Al₂O₃) may have a higher dielectric constant (i.e., high-k) than that of the silicon oxide layer.

The data storage layer 123 may include a silicon nitride layer (e.g., Si₃N₄). The data storage layer 123 may be referred to as a charge trap layer.

The tunnel insulating layer 125 may include an oxide layer (e.g., silicon oxide, SiO₂) or metal organic frameworks (MOF).

The channel layer 127, the tunnel insulating layer 125, the data storage layer 123, and the blocking insulating layer 121 may be formed in various structures.

In the illustrated embodiment of FIG. 2, the blocking insulating layer 121, the data storage layer 123, and the tunnel insulating layer 125 may extend in the Z-axis direction along the sidewall of the channel layer 127. However, at least one of the blocking insulating layer 121, the data storage layer 123, and the tunnel insulating layer 125 may be disposed in pocket areas in which the gate electrodes 103 are recessed.

Meanwhile, in order to increase the integration in a three-dimensional NAND device, various scaling schemes have been developed. For example, the scaling schemes include a logical scaling (e.g., a single-level cell (SLC), a multi-level cell (MLC), a triple-level cell (TLC), a quad-level cell (QLC), a penta-level cell (PLC)), a vertical scaling (e.g., 100 stacks (tiers), 200 stacks, 300 stacks, 400 stacks), a lateral scaling (e.g., 3 rows between a slit to a slit as one block, 9 rows, 19 rows, in which higher rows mean higher density), and a structural scaling (e.g., 4 dimension (4D), Periphery under Cell Array (PUA), Hybrid Wafer Bonding (HWB)).

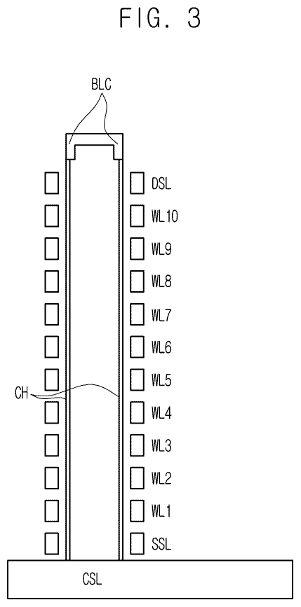

FIG. 3 is a diagram for describing a configuration of a semiconductor memory device. In FIG. 3, a schematic configuration of a memory cell string of a three-dimensional NAND device is illustrated.

Referring to FIG. 3, the memory cell string may include a source select transistor, a plurality of memory cells, and a drain select transistor connected in series between a common source line CSL and a bit line contact BLC. In the figure, a channel CH, a source select line SSL corresponding to the source select transistor, a plurality of word lines WL1 to WL10 corresponding to the memory cells, and a drain select line DSL corresponding to the drain select transistor are illustrated. Further, the memory cell string may be coupled to a bit line though the bit line contact BLC.

In general, the channel CH may be formed of polycrystalline-silicon which is also referred to as poly-silicon.

An erase operation of the three-dimensional NAND device usually relies on holes in the channel CH, generated by a gate-induced drain leakage (GIDL) mechanism.

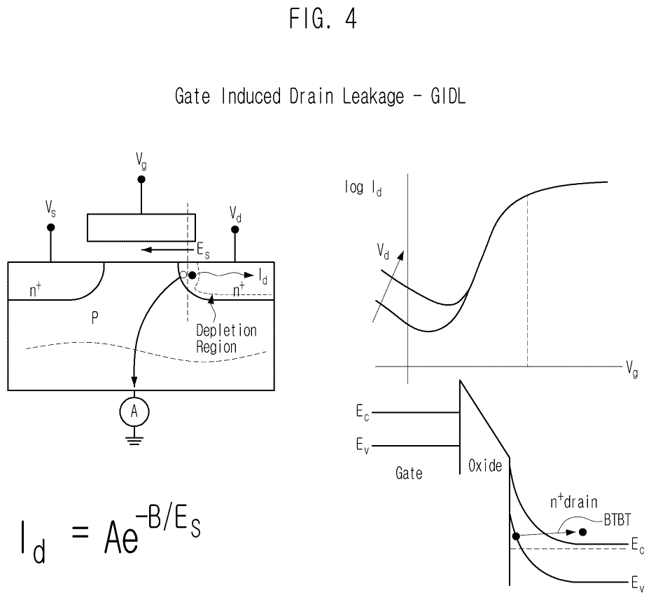

FIG. 4 is a diagram for describing GIDL mechanism. In FIG. 4, V_{g} denotes a gate voltage, Vₛ denotes a source voltage V_{d} denotes a drain voltage, and I_{d} denotes a drain current.

As shown in FIG. 4, GIDL is a process of electron tunneling from a valence band to a conduction band. Leakage current is generated between a drain and a bulk (i.e., a substrate or a well region) due to electron-hole pairs generated by tunneling of valence band electrons into a conduction band. That is, GIDL is induced by the band-to-band tunneling (BTBT or B2B) effect and generated in a gate-to-drain overlap region.

Due to its nature, GIDL is very sensitive to tunneling barrier which is a function of electrical field and material band gap value. That is, BTBT is enhanced in a drain region when the drain voltage V_{d} is greater than the gate voltage V_{g}, thereby forming deep depletion in the drain region. Moreover, due to requirement of the conservation of momentum, an indirect band gap material, such as Si, has less tunneling probability than a direct band gap material.

In spite of having an indirect band gap, a poly-silicon channel has multiple grain boundaries with associated trap sites which can help the GIDL process to secure GIDL efficiency during an erase operation. However, the poly-silicon channel has disadvantages in terms of conductivity.

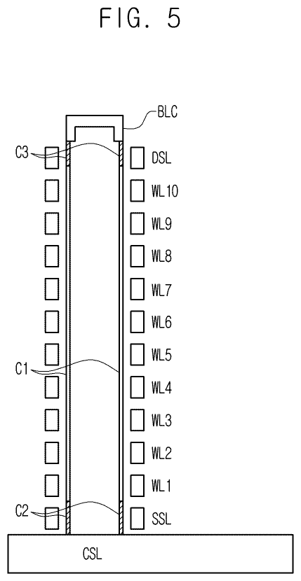

FIG. 5 is diagram for describing a configuration of a semiconductor memory device in accordance with one embodiment of the present disclosure. In FIG. 5, a schematic configuration of a memory cell string of a three-dimensional NAND device is illustrated.

Referring to FIG. 5, the memory cell string may include a source select transistor, a plurality of memory cells, and a drain select transistor connected in series between a common source line CSL and a bit line contact BLC. In the figure, a channel, a source select line SSL corresponding to the source select transistor, a plurality of word lines WL1 to WL10 corresponding to the memory cells, and a drain select line DSL corresponding to the drain select transistor are illustrated. Further, the memory cell string may be coupled to a bit line though the bit line contact BLC. However, the numbers of the source select line SSL, word lines WL1 to WL10, and the drain select line DSL may vary depending on a device design.

The channel may include a first channel layer C2, a second channel layer C1, and a third channel layer C3. The first channel layer C2, the second channel layer C1, and the third channel layer C3 may be disposed along a sidewall of a channel hole (e.g., 111 in FIG. 2).

The first channel layer C2 may correspond to the source select transistor coupled to the source select line SSL. The second channel layer C1 may correspond to the memory cells coupled to the word lines WL1 to WL10. The third channel layer C3 may correspond to the drain select transistor coupled to the drain select line DSL.

In an embodiment, the second channel layer C1 may include molybdenum disulfide (MoS₂). Further, the second channel layer C1 may include tungsten disulfide (WS₂), tungsten diselenide (WSe₂), or any combination (i.e., compound) of transition metal and a group 6 element in the periodic table. Further, the second channel layer C1 may include an oxide semiconductor material such as zinc oxide (ZnO), cerium(IV) oxide (CeO₂), titanium dioxide (TiO₂), magnesium oxide (MgO), tin(IV) oxide (SnO₂), zirconium dioxide (ZrO₂), or indium gallium zinc oxide (IGZO). For example, the molybdenum disulfide may be formed as a monolayer, multi-monolayers, or an ultra-thin layer. The molybdenum disulfide may be formed to have a thickness ranging from 1 nm to 6 nm.

In an embodiment, each of the first channel layer C2 and the third channel layer C3 may include poly-silicon which is doped with, for example, an N-type dopant such as phosphorous (P). For example, the poly-silicon may be formed to have a thickness raging from 4 nm to 15 nm.

In an embodiment, a poly-silicon layer may be first deposited or grown within an area corresponding to the source select line SSL, and then a molybdenum disulfide layer may be deposited or grown on a remaining area which corresponds to the word lines WL1 to WL10 and the drain select line DSL. After performing an etch back process on the molybdenum disulfide layer, another poly-silicon layer may be deposited or grown within an area corresponding to the drain select line SSL.

The molybdenum disulfide layer may be formed by using Metal Organic Chemical Vapor Deposition (MOCVD), Atomic Layer Deposition (ALD), thermal ALD, Pulsed Laser Deposition (PLD), or epitaxial growth. Further, Metal-Induced Lateral Crystallization (MILC) may be used to form the poly-silicon layer.

The molybdenum disulfide layer may be formed by using Metal Organic Chemical Vapor Deposition (MOCVD), Atomic Layer Deposition (ALD), thermal ALD, Pulsed Laser Deposition (PLD), or epitaxial growth.

The source select line SSL, the word lines WL1 to WL10, and the drain select line DSL may be formed of at least one of TiN, TiAlN, TiN/W, TaN, HfN, Molybdenum (Mo), and Ruthenium (Ru).

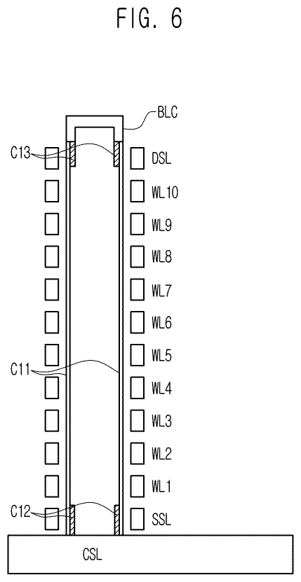

FIG. 6 is diagram for describing a configuration of a semiconductor memory device in accordance with another embodiment of the present disclosure. In FIG. 6, a schematic configuration of a memory cell string of a three-dimensional NAND device is illustrated.

Referring to FIG. 6, the memory cell string may include a source select transistor, a plurality of memory cells, and a drain select transistor connected in series between a common source line CSL and a bit line contact BLC. In the figure, a channel, a source select line SSL corresponding to the source select transistor, a plurality of word lines WL1 to WL10 corresponding to the memory cells, and a drain select line DSL corresponding to the drain select transistor are illustrated. Further, the memory cell string may be coupled to a bit line though the bit line contact BLC. However, the numbers of the source select line SSL, word lines WL1 to WL10, and the drain select line DSL may vary depending on a device design.

The channel may include a first channel layer C12, a second channel layer C11, and a third channel layer C13.

The second channel layer C11 may be disposed to correspond to the source select line SSL, the word lines WL1 to WL10, and the drain select line DSL, along a sidewall of a channel hole (e.g., 111 in FIG. 2).

The first channel layer C12 may be disposed on a surface of the second channel layer C11, which is exposed toward the channel hole, to correspond to the source select line SSL.

The third channel layer C13 may be disposed on the surface of the second channel layer C11, which is exposed toward the channel hole, to correspond to the drain select line DSL.

The source select transistor coupled to the source select line SSL may have a channel including the first channel layer C12 and the second channel layer C11. Further, the drain select transistor coupled to the drain select line DSL may have a channel including the second channel layer C11 and the third channel layer C13. Further, the memory cells coupled to the word lines WL1 to WL10 may have a channel of the second channel layer C11.

In an embodiment, the second channel layer C11 may include molybdenum disulfide (MoS₂). Further, the second channel layer C11 may include tungsten disulfide (WS₂), tungsten diselenide (WSe₂), or any combination (i.e., compound) of transition metal and a group 6 element in the periodic table. Further, the second channel layer C1 may include an oxide semiconductor material such as zinc oxide (ZnO), cerium(IV) oxide (CeO₂), titanium dioxide (TiO₂), magnesium oxide (MgO), tin(IV) oxide (SnO₂), zirconium dioxide (ZrO₂), or indium gallium zinc oxide (IGZO). For example, the molybdenum disulfide may be formed as a monolayer, multi-monolayers, or an ultra-thin layer. The molybdenum disulfide may be formed to have a thickness ranging from 1 nm to 6 nm.

In an embodiment, each of the first channel layer C12 and the third channel layer C13 may include poly-silicon which is doped with, for example, an N-type dopant such as phosphorous (P). For example, the poly-silicon may be formed to have a thickness raging from 4 nm to 15 nm.

In an embodiment, a molybdenum disulfide layer may be first deposited or grown on the sidewall of the channel hole (e.g., 111 in FIG. 2), and then a poly-silicon layer may be additionally formed on the molybdenum disulfide layer of areas which correspond to the source select line SSL and the drain select line DSL. To this end, the selective deposition of the poly-silicon layer by using an inhibition layer.

The molybdenum disulfide layer may be formed by using Metal Organic Chemical Vapor Deposition (MOCVD), Atomic Layer Deposition (ALD), thermal ALD, Pulsed Laser Deposition (PLD), or epitaxial growth. Further, Metal-Induced Lateral Crystallization (MILC) may be used to form the poly-silicon layer.

The source select line SSL, the word lines WL1 to WL10, and the drain select line DSL may be formed of at least one of TiN, TiAlN, TiN/W, TaN, HfN, Molybdenum (Mo), and Ruthenium (Ru).

In accordance with the embodiments of the present disclosure, a hybrid channel is proposed by combining poly-silicon and molybdenum disulfide (MoS₂).

The poly-silicon (or poly-silicon/molybdenum combination) provided for channels of the source and drain select transistors can secure the GIDL efficiency, thereby providing a good enough speed during an erase operation.

The molybdenum disulfide provided for channels of the memory cells can secure the improved conductivity for the memory cells.

The molybdenum disulfide (MoS₂) has an indirect band gap (Eg) of about 1.2 eV for thicker film, and a direct band gap of about 1.8 eV for a monolayer (or an ultra-thin layer), which is not good in view of the GIDL efficiency. However, the molybdenum disulfide (MoS₂) has electron mobility greater than 100 cm²/(V·s) when deposited as a monolayer. Accordingly, the channel current can be enhanced, enabling further cell string layers to be stacked. In addition, the gate control and the channel boosting efficiency can be improved during a program inhibit operation.

According to the above-described embodiments of the present disclosure, a cell formation process may proceed without complexity.

While the embodiments of the present disclosure described a case where polysilicon is applied to channels for both the source select line(s) and the drain select line(s), polysilicon may be applied to only one of the source select line(s) and the drain select line(s) depending on a device design.

Further, while the embodiments of the present disclosure contain many specifics, these should not be construed as limitations on the scope of the present disclosure or of what may be claimed, but rather as descriptions of features that may be specific to particular embodiments of the present disclosure. Certain features that are described in the context of separate embodiments can also be implemented in combination to form a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Only a few implementations and embodiments are described and other implementations, embodiments, enhancements and variations can be made based on what is described and illustrated in the present disclosure. Furthermore, the embodiments may be combined to form additional embodiments.

What is claimed is:

1. A three-dimensional semiconductor memory device comprising a cell string including at least one select transistor, a plurality of memory cells, and at least one drain select transistor connected in series between a common source line and a bit line, wherein:
the at least one source select transistor has a first channel including a first polysilicon layer; and
each of the plurality of memory cells has a second channel containing a material other than polysilicon.

2. The three-dimensional memory device of claim 1, wherein the at least one drain select transistor has a third channel including a second polysilicon layer.

3. The three-dimensional memory device of claim 1, wherein:
the first channel includes a stack of a material layer and the first polysilicon layer, the material layer containing the material other than polysilicon;
the third channel includes a stack of the material layer and the second polysilicon layer; and
the material layer contains the material other than polysilicon.

4. The three-dimensional memory device of claim 1, wherein the first channel consists of the first polysilicon layer.

5. The three-dimensional memory device of claim 2, wherein the third channel consists of the second polysilicon layer.

6. The three-dimensional memory device of claim 1, wherein the material other than polysilicon includes a compound of transition metal and a group 6 element in a periodic table.

7. The three-dimensional memory device of claim 6, wherein the compound contains one of a molybdenum disulfide (MoS₂), a tungsten disulfide (WS₂), a tungsten diselenide (WSe₂), zinc oxide (ZnO), cerium(IV) oxide (CeO₂), titanium dioxide (TiO₂), magnesium oxide (MgO), tin(IV) oxide (SnO₂), zirconium dioxide (ZrO₂), and indium gallium zinc oxide (IGZO).

8. The three-dimensional memory device of claim 3, wherein:
the material layer has a thickness raging from 1 nm to 6 nm; and
each of the first polysilicon layer and the second polysilicon layer has a thickness raging from 4 nm to 15 nm.

9. The three-dimensional memory device of claim 4, wherein the first polysilicon layer of the first channel has a thickness raging from 4 nm to 15 nm.

10. The three-dimensional memory device of claim 5, wherein the second polysilicon layer of the third channel has a thickness raging from 4 nm to 15 nm.

11. The three-dimensional memory device of claim 1, wherein the second channel includes a monolayer, multi-monolayers, or an ultra-thin layer, each of which contains the material other than polysilicon and has a thickness raging from 1 nm to 6 nm.

12. A three-dimensional semiconductor memory device comprising a cell string including at least one select transistor, a plurality of memory cells, and at least one drain select transistor connected in series between a common source line and a bit line, wherein:
the at least one drain select transistor has a first channel including a polysilicon layer; and
each of the plurality of memory cells has a second channel containing a material other than polysilicon.

13. The three-dimensional memory device of claim 12, wherein the first channel includes a stack of a material layer and the polysilicon layer, the material layer containing the material other than polysilicon.

14. The three-dimensional memory device of claim 12, wherein the first channel consists of the polysilicon layer.

15. The three-dimensional memory device of claim 12, wherein the material other than polysilicon includes a compound of transition metal and a group 6 element in a periodic table.

16. The three-dimensional memory device of claim 15, wherein the compound contains one of a molybdenum disulfide (MoS₂), a tungsten disulfide (WS₂), a tungsten diselenide (WSe₂), zinc oxide (ZnO), cerium(IV) oxide (CeO₂), titanium dioxide (TiO₂), magnesium oxide (MgO), tin(IV) oxide (SnO₂), zirconium dioxide (ZrO₂), and indium gallium zinc oxide (IGZO).

17. The three-dimensional memory device of claim 13, wherein:
the material layer has a thickness raging from 1 nm to 6 nm, and
the polysilicon layer has a thickness raging from 4 nm to 15 nm.

18. The three-dimensional memory device of claim 14, wherein the polysilicon layer of the first channel has a thickness raging from 4 nm to 15 nm.

19. The three-dimensional memory device of claim 12, wherein the second channel includes a monolayer, a monolayer, multi-monolayers, or an ultra-thin layer, each of which contains the material other than polysilicon and has a thickness raging from 1 nm to 6 nm.
